(19) United States
(12) Patent Application Publication
(10) Pub. No.: US 2011/0097571 A1
(43) Pub. Date: Apr. 28, 2011

(54) OLEOPHOBIC, AIR PERMEABLE, AND BREATHABLE COMPOSITE MEMBRANE

(75) Inventors: Yit-Hong Tee, Lee's Summit, MO (US); Taher Abujoudeh, Lee's Summit, MO (US); Martin Hatfield, Odessa, MO (US)

(73) Assignee: BHA Group, INC., Kansas City, MO (US)

(21) Appl. No.: 12/603,740

(22) Filed: Oct. 22, 2009

(51) Int. Cl. B32B 3/26; B05D 5/00; C23C 16/513

(52) U.S. Cl. 428/315.9; 427/243; 427/569

(57) ABSTRACT

A porous composite membrane is provided by an associated method and includes a first microporous substrate of a first material. A second, coating material is joined to the first microporous substrate to form a bi-component arrangement with the first microporous substrate. The second material is different than the first material. A third, coating material is applied to the bi-component arrangement. The third material is different than the first and second materials. The third material extending over at least a portion of surfaces of the bi-component arrangement which define the micropores.

### FIELD OF THE INVENTION

The present invention relates generally to sheet materials, which can be referred to as membranes or films, and more particularly, to sheet materials that have qualities such as being oil penetration resistant, water penetration resistant, water vapor permeable, air permeable and resistant to significant property degradation resulting from chemical presence.

### BACKGROUND OF THE INVENTION

Fluoropolymers and thermoplastic elastomers are known and are used in many different applications, including outdoor sheet materials or films. A layer of fluoropolymer or a layer of thermoplastic elastomer may be utilized to provide some desired properties, such as water vapor and air-permeable (e.g., breathability) or resistance to water penetration. Thus, it is known to provide a breathable and water resistant sheet material. Such a sheet material is very useful in active outdoor applications. For example, such sheet material can be used to make articles of clothing, outdoor gear, protective articles and the like. However, the presence of some chemicals, such as insect repellant, may cause degradation of at least some of the properties of the sheet material, such as the level of water penetration resistance. Specifically, the propensity that the sheet material will permit penetration/passage of water will be increased due to the chemical presence on the sheet material. Such increased propensity to permit penetration/passage of water may be referred to as wetting out.

### BRIEF SUMMARY OF THE INVENTION

The following presents a simplified summary of the invention in order to provide a basic understanding of some example aspects of the invention. This summary is not an extensive overview of the invention. Moreover, this summary is not intended to identify critical elements of the invention nor delineate the scope of the invention. The sole purpose of the summary is to present some concepts of the invention in simplified form as a prelude to the more detailed description that is presented later.

In accordance with one aspect, the present invention provides a porous composite membrane that includes a first microporous substrate of a first material. A second, coating material is joined to the first microporous substrate and is a second microporous substrate to form a bi-component arrangement with the first microporous substrate. The second material is different than the first material. A third, coating material is applied to the bi-component arrangement. The third material is different than the first and second materials. The third material extending over at least a portion of surfaces of the bi-component arrangement which define the micropores.

In accordance with another aspect, the present invention provides an associated method of providing the porous composite membrane.

### BRIEF DESCRIPTION OF THE DRAWINGS

The foregoing and other aspects of the present invention will become apparent to those skilled in the art to which the present invention relates upon reading the following description with reference to the accompanying drawings, in which:

FIG. 1 is an enlarged schematic edge view of an example waterproof, water vapor-permeable and air-permeable sheet material according to one aspect of the present invention;

FIG. 2 is an enlarged, schematic view of a portion of the material of FIG. 1 and shows open microscopic porosity defined by fibrils connected at nodes; and

FIG. 3 is a further enlarged view of a portion of FIG. 2 and is sectioned to shown constituent members of the sheet material that include a substrate, with a layer and coating upon a substrate that are non-blocking of the porosity of the material.

### DETAILED DESCRIPTION OF THE INVENTION

Example embodiments that incorporate one or more aspects of the present invention are described and illustrated in the drawings. These illustrated examples are not intended to be a limitation on the present invention. For example, one or more aspects of the present invention can be utilized in other embodiments and even other types of devices. Moreover, certain terminology is used herein for convenience only and is not to be taken as a limitation on the present invention. Still further, in the drawings, the same reference numerals are employed for designating the same elements.

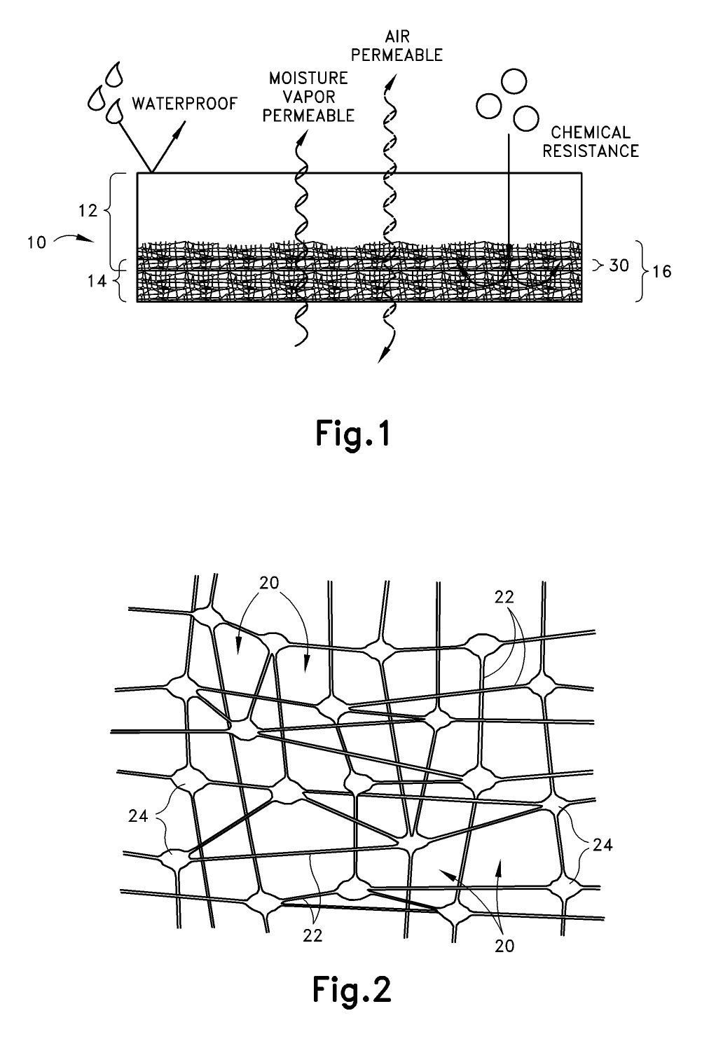

Turning to FIG. 1, an example in accordance with an aspect of the present invention is shown. Specifically, the example shows an oleophobic, air permeable, and moisture vapor permeable composite membrane sheet material 10 that is waterproof. The terminology of “sheet material” is to include membrane or film. In the shown example, the sheet material includes a waterproof porous polymer substrate 12, a porous thermoplastic layer 14 joined to the polymer substrate, and an oleophobic coating 16 joined to at least some of the thermoplastic layer material and the polymer substrate material. It is worth noting that within FIG. 1 shading to represent the oleophobic coating 16 is provided. This shading is only to permit identification/distinction from the substrate 12 and thermoplastic layer 14, and is not intended to indicate sectioning. It is to be clearly understood that FIG. 1 is a schematic representation. The substrate 12, the thermoplastic coating layer 14, and the oleophobic coating 16 can be considered to be constituent portions of the sheet material 10 and thus provide a sheet material 10 that is oleophobic, air-permeable, water vapor-permeable, waterproof, and resistance to change that would be caused by a chemical challenge agent. It is to be appreciated that waterproof is intended to mean the commonly understood resistance to penetration of non-vapor water at standard or ambient conditions. It is to be further appreciated that in one specific example, waterproof can be defined as meeting ISO₈₁₁ standard of 14.50 psi (1000 milibars) water pressure hold-up before any observed penetration or leakage through the material's surface. However, specific adherence to the ISO811 standard is not necessary.

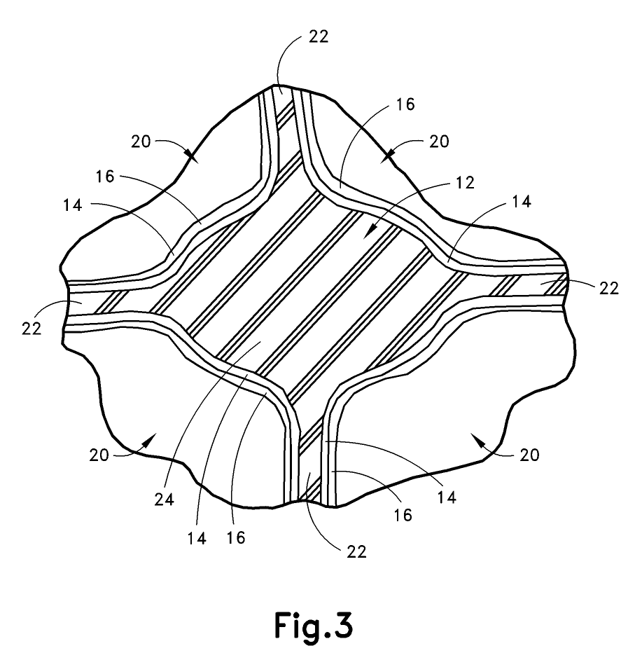

Focusing upon the porous substrate 12, the substrate has air-permeable, vapor-permeable and waterproof characteristics. Pores 20 of the substrate 12 are micropores. See FIG. 2 in which only some of the many pores are labeled with the reference number 20. In some specific examples, the porous substrate 12 (FIG. 1) includes at least one of the following materials: fluoro-based polymer (fluoropolymer), polyurethane, cellulosic polymer, polyamide, polyimide, polycarbonate, sulfonated polymer/polysulfone, and copolymer. The fluoro-based polymer includes at least one of polytetrafluoroethylene and polyvinylidene fluoride. The copolymer includes at least one copolyester-polyether and copolyether-polyamide. A further specific example for the porous substrate 12 is expanded polytetrafluoroethylene (ePTFE) or microporous membrane. The substrate 12 resists water droplet penetration by its relatively small pore size, surface energy of the material of the substrate relative to the surface tension of a water droplet located thereon. As mentioned, FIG. 2 shows the porosity. In the shown example, the substrate has a microscopic structure that is based upon fibrils 22 that extend and interconnect nodes 24 (only some are identified with the reference numbers 22, 24). The fibrils 22 and nodes 24 define the pores 20. In some examples, the pores 20 may be in the range of 0.01 microns to 10 microns in diameter.

Focusing upon the thermoplastic layer 14 (see FIG. 1), the layer also is porous. In particular, the pores are micropores. This porosity provides for air-permeable and water vapor-permeable characteristics. The layer 14 resists chemical challenge by its relatively small pore size, surface energy of the material of the substrate 12 relative to the surface tension of the challenge agent and contact there between. In one definition, the layer 14 may be described as having a chemical resistance. In particular, the layer 14 is resistant to the affect of one or more chemicals that would cause the sheet material 10 to otherwise lose a waterproof characteristic. As some examples, the layer 14 may be thermoplastic polyurethane (TPU) or thermoplastic elastomers (TPE) of copolymeric-based systems such as polyether-polyesters or polyether-polyamides copolymers. In general, the material of the layer includes at least one of polyurethane, fluorinated acrylate, fluorinated methacrylate, siloxane-based polymer, polyacrylic acid, copolymers of acrylamide. In some specific examples the material is a thermoplastic or a thermoset. Also, in some specific examples, the material is crosslinkable. With regard to FIG. 1 in general, it is to be appreciated that the dimensions (i.e., length, width and thickness) of the sheet material may be varied, and the representations schematically shown in the Figure are not to be used for dimension, characteristic or property limitations.

In one embodiment of this disclosure, to provide the thermoplastic layer 14 onto the sheet material 10, the layer 14 is heated to at least partially melt. While in the at least partially melted state, the layer material flows into pores of the substrate 12. The coating layer material only proceeds partially into the substrate 12. This partial flow into the substrate 12 is schematically indicated in FIG. 1 via the overlap of the bracketed areas for references numbers 12 and 14. Specifically in the example the layer 14 extends into the pores at just an adjacent first portion or segment 30 of the substrate 12. This thermo-flow filling provides for the substrate 12 and the layer 14 to be bonded together. Or in other words, the layer 14 is thermally laminated to the substrate 12 while retaining the open pore structures of the substrate 12 and layer 14.

The material of the layer 14 adheres to fibrils 22 and nodes 24 of the material of the substrate 12. FIG. 3 schematically shows one possible joining attachment of the thermoplastic material 14 on fibrils 22 and nodes 24 of the substrate material 12. It is to be appreciated that the enlargement shown in the FIG. 3 example is from the area of overlap 30 shown in FIG. 1. Also, it is to be appreciated that the example of FIG. 3 shows that the layer 14 covers all of the surfaces of the fibrils 22 and nodes 24 of the material of the substrate 12. Also, it is to be appreciated that the example of FIG. 3 shows the layer 14 is uniform and somewhat thin compared to the fibrils 22 and nodes 24 of the material of the substrate 12. It is to be appreciated that the layer 14 may be of varied thickness/thinness, the layer may fill more/less of the pore volume 20 provided within substrate, and/or may not completely cover all available surfaces of the fibrils and nodes of the material of the substrate.

In one example, the heating of the layer 14 is performed in a series of heating steps. In one specific example the heating includes heating at a first temperature, subsequently heating at a second temperature that is higher than the first temperature, and then subsequently heating at a third temperature that is higher than the second temperature. A specific example of the multi-temperature heating includes heating at the first temperature in the range of 80-90° C., subsequently heating at the second temperature in the range of 90-110° C., and subsequently heating at the third temperature in the range of 110-150° C.

The heating of the layer 14 may be accomplished via different methods. In one example, the heating is accomplished in conjunction with application of pressure to the sheet material. In one specific example, the heating and pressure may be imparted via passing an intermediate-step sheet material 10 (i.e., the substrate 12 with the layer 14 applied but not yet heated) through heated press rollers. Such an approach of using heated rollers is useful if the sheet material 10 is manufactured as an elongate web. The elongate web of sheet material may be moved to pass between the heated rollers at a web speed so that large quantities of the sheet material may be produced in an economical manner. With the regard to the specific example of providing heat in a series of steps, the heating may be accomplished via a series of heated rollers, with each roller providing a different heating level. Of course, other forms of heating and pressure application, such as non-dynamic heating and pressing, are contemplated and within the scope of the present invention.

With reference to FIG. 1, the substrate 12 is hydrophobic and is also air and water vapor-permeable. These features are schematically shown in FIG. 1. As mentioned, one example material of the substrate 12 is microporous, expanded polytetrafluoroethylene. The fluoropolymer has a three-dimensional lattice type of structure that yields a plurality of microporous openings through a tortuous path that define pores small enough to prevent the passage of water droplets yet large enough to allow the passage of air and vapor. For reference, a droplet of liquid water is about 1000 times larger than the size of water in the vapor state.

The oleophobic and hydrophobic coating 16 attaches to join to at least some of the thermoplastic layer material 14 and the polymer substrate material 12. Specifically, the oleophobic coating 16 attaches to the material of the thermoplastic layer 14 and the material of the polymer substrate 12 at the microporosity level. By this the oleophobic coating 16 does not lay upon an exterior of the thermoplastic layer 14 and/or the polymer substrate 12. Instead the oleophobic coating 16 is penetrated into the material of the thermoplastic layer 14 and the material of the polymer substrate 12. Again with reference to the example of FIG. 3, the oleophobic coating 16 is on the layer 14. However, it is to be appreciated that the oleophobic coating 16 may also be located on the portions of the substrate 12 and/or layer 14 that are not intermingled (i.e., outside the overlap area 30 See FIG. 1). As such, the oleophobic coating 16 may be on the substrate 12 directly and/or oleophobic coating 16 may be on layer 14 that is not extending into the porosity of the substrate 12 and thus is not the material of the substrate at the microscopic level. Also, it is to be appreciated that the example of FIG. 3 shows that the coating 16 covers all of the surfaces of the layer 14 that is on all of the fibrils 22 and the nodes 24 of the material of the substrate 12. Also, it is to be appreciated that the example of FIG. 3 shows the coating 16 is uniform and somewhat thin compared to the fibrils 22 and nodes 24 of the material of the substrate 12. It is to be appreciated that the coating 16 may be of varied thickness/thinness, the coating may fill more/less of the pore volume 20 provided within substrate, and/or may not completely cover all available surfaces of the layer 14 upon the fibrils 22 and nodes 24 of the material of the substrate 12.

The oleophobic coating 16 may be fluoroacrylate-based or siloxane-based polymers or other oleophobic material. In general, the material of the coating 16 includes at least one of polyurethane, fluorinated acrylate, fluorinated methacrylate, siloxane-based polymer, polyacrylic acid, copolymers of acrylamide. The material may be a thermoplastic or a thermoset. In one example, oleophobic coating material 16 is introduced into the sheet material 10 in a dissolved state. Also, as an example, the oleophobic coating material 16 is introduced into the sheet material 10 in condition that may be considered fluid to permit motion/movement. In one specific example, the oleophobic coating material 16 is dissolved by pressurized fluid of carbon dioxide under supercritical conditions and moves oleophobic coating material into the porous substrate 12 and/or porous layer 14. The oleophobic coating is attached/deposited into the porous substrate 12 and/or porous layer 14 by lowering the pressure from supercritical to non-supercritical condition.

It is to be appreciated that the process of making the overall end product may be varied. For example, the material of the coating 16, may be applied various techniques including dispersion in a fluid, with the aid of a liquid carrier, and deposited by precipitation from a supercritical fluid, liquid, or gas. If a liquid carrier is used, the carrier may be either an organic solvent or an inorganic solvent. It is to be noted that with the use of a supercritical solvent, the solvent may be carbon dioxide in either fluid, liquid, or gas state. As such, the process may include many different techniques such as utilizing chemical vapor deposition, plasma, knife coating process, transfer coating process, screen printing process, and gravure roll printing process. Even other techniques are possible and contemplated.

The final treated (i.e., layered and coated) substrate remains porous making the sheet material 10 moisture vapor permeable, air permeable, waterproof, durable, resistant to chemical penetration, and oleophobic. The final sheet or membrane has an air permeability of at least 0.1 cfm per square foot of surface area of one side of the composite membrane at 1,000 Pascals differential pressure. This is due in part to the micropores being less than 100 microns. The final sheet material can be combined with optional layers, such as nonwoven and woven fabrics, yarns, knitted fabrics, for different consumer, professional, and industrial applications.

Within the prepared sheet material 10, the characteristics of waterproofness, water vapor permeability, air permeability are provided. Waterproofness is the commonly understood terminology associated with the ability to prevent non-vapor water from penetrating the sheet material. Water vapor permeability is the ability to permit passage of water vapor through the sheet material. Air permeability is the ability to permit passage of air through the sheet material. Moisture vapor transmission rate, also known as MVTR, is a measure of the passage of water vapor through a sheet material expressed in grams/meter²/day. Air permeability, expressed in cubic feet per minute, measures the time it takes for air to pass through the sample at a predetermined pressure drop of water across the sample. A high MVTR and air permeability results in good comfort levels since sweat and body heat pass through the membrane and are permitted to quickly move from adjacent the body.

At least one of the materials of the layer 14 and the coating material 16 changes oil repellent properties of the substrate 12. In particular, such properties are enhanced. At least one of the materials of the layer 14 and the coating material 16 increases resistance to liquid chemical intrusion into or through the pores of the substrate 12. In accordance with one aspect of the present invention, waterproofness, water vapor permeability, air permeability are provided even if a chemical that would otherwise degrade resistance to water penetration of the sheet material 10. The chemical may be considered to be a challenge agent. Such a challenge agent has at least a potential to cause an adverse affect to at least one desirable characteristic. In a specific example, the challenge agent has at least the potential to adversely affect the characteristic of being waterproof. A loss of waterproofness is associated with wetting and water penetration. By this, wetting-out could occur that would allow passage of non-vapor or liquid water. Accordingly, it is to be understood that reference to a chemical may be considered to include an understanding that the chemical is such a challenge agent. A resistance to degradation by chemical (challenge agent) is indicated by Mullen test rating (ASTM D751).

One widely used example chemical (i.e., challenge agent) that could cause the degradation of the non-vapor water penetration resistance (i.e., waterproofness) of the sheet material 10 is N,N-Diethyl-meta-toluamide, also known as DEET. Other examples of chemicals that could cause degradation include chemicals present include engine fuels (e.g., aviation, automotive, diesel) and solvents. Still further, other chemical contaminants, such as a variety of acids, are also contemplated. As mentioned, such chemicals are sometimes referred to as challenge agents because of their propensity to degrade desirable material properties. Of course the particular chemical challenge agents are not limitations on the present invention. Such chemicals, if present on the sheet material 10 would otherwise cause the microporous material of the substrate 12 to permit passage of water droplets, but one aspect of the present invention prevents such unwanted occurrence (i.e., loss of waterproofness) and thus provides a resistance to such chemicals.

DEET is a common active ingredient in insect repellents and has a relatively low surface tension that could “foul” the substrate 12 and sheet material 10 and permit the passage of liquid water therethrough. Since the sheet material 10 may be used in outdoor applications, such as in gloves, boots, tents, etc., it is beneficial for the sheet material 10 to be resistant to degradation of the waterproof property from a chemical challenge agent, such as DEET, used in insect repellant. This resistance to degradation allows the sheet material 10 to retain its waterproof, vapor permeable, and air permeable characteristics despite the presence of the chemical. Also, the sheet material 10 may be used in applications where sheet materials may contact an engine fuel (e.g., diesel fuel). Again, is it is beneficial for the sheet material 10 to be resistant to degradation of the waterproof property from a chemical challenge agent such as engine fuel.

The sheet material 10 can retain the resistance to degradation even after many hours of exposure to the challenge agent. Data for some example sheet materials includes ePTFE alone, before and after treatment with Supercritical CO₂ with Fluoro-polymer, ePTFE with just a thermoplastic polyurethane layer (i.e., no treatment with Supercritical CO₂ with Fluoro-polymer), and two examples in accordance with the present invention (e.g., ePTFE coated with microporous thermoplastic polyurethane and treated with oleophobic coating) is shown in tables 1A-1C. As such, at least one the materials of the layer 14 and the coating 16 changes the hydrophobic or water repellent properties of the substrate 12. Along these lines at least one the materials of the layer 14 and the coating 16 changes the coefficient of friction of the substrate 12.

TABLE 1A

| | | MVTR | |
|---|---|---|---|
| | | (g/m²/day) | |
| | | (JIS L1099 B - | Air Perm |
| | | Inverted Cup | (cfm) (ASTM |
| Sample Info | Remarks | Method) | D737) |
| ePTFE | Pristine ePTFE | 52,883 | 0.15 |
| | membrane before | | |
| | treatment with | | |
| | Supercritical | | |
| | CO2 with | | |
| | Fluoro-polymer | | |
| ePTFE | Pristine ePTFE | 56,404 | 0.11 |
| | membrane after | | |
| | treatment with | | |
| | Supercritical | | |
| | CO2 with | | |
| | Fluoro-polymer | | |
| ePTFE coated with | Before treatment | 41,761 | 0.125 |
| microporous | of Supercritical | | |
| thermoplastic | CO2 with | | |
| polyurethane | Fluoro-polymer | | |
| ePTFE coated with | After treatment | 42,716 | 0.12 |
| microporous | (Supercritical | | |
| thermoplastic | CO2 with | | |
| polyurethane and | Fluoro-Polymer) | | |
| treated with | | | |
| oleophobic | | | |
| fluoroacrylate | | | |
| polymer | | | |
| ePTFE coated with | After treatment | 42,912 | 0.12 |
| microporous | (Supercritical | | |
| thermoplastic | CO2 with | | |
| polyurethane and | Fluoro-Polymer) | | |
| treated with | followed by Heat | | |
| oleophobic | Treatment at | | |
| fluoroacrylate | 125° C. for | | |
| polymer | 1 hour | | |

TABLE 1B

| | | Sustained Low | |
|---|---|---|---|
| | | Pressure | |
| | Mullen after 16-hr | Hydrostatic Test at | |
| | Exposure to | 1 psi/10 min after 16- | |
| | DEET (N,N- | hr DEET (N,N- | |
| | Diethyl-meta- | Diethyl-meta- | |
| | toluamide) (psi) | toluamide) (AATCC | |
| Sample Info | (ASTM D751) | 127) | Durability Wash |
| ePTFE | 50 | Failed | NA |
| | (140 before DEET) | | |
| ePTFE | 15 | Failed | NA |
| | (107 before DEET) | | |
| ePTFE coated with | 95 | Passed with no | No delamination |
| microporous | | leakage | after 200 hours |
| thermoplastic | | | continuous |
| polyurethane | | | agitation in water |
| | | | (25° c.) |
| ePTFE coated with | 98 | Passed with no | No delamination |
| microporous | | leakage | after 200 hours |
| thermoplastic | | | continuous |
| polyurethane and | | | agitation in water |
| treated with | | | (25° c.) |
| oleophobic | | | |
| fluoroacrylate | | | |
| polymer | | | |
| ePTFE coated with | 94 | Passed with no | No delamination |
| microporous | | leakage | after 200 hours |
| thermoplastic | | | continuous |
| polyurethane and | | | agitation in water |
| treated with | | | (25° c.) |
| oleophobic | | | |
| fluoroacrylate polymer | | | |

TABLE 1C

| | 2000 cycles | Sustained | | |
|---|---|---|---|---|
| | Gelbo Flex at | Low | | |
| | 25° C. | Pressure | | |
| | (ASTM F 392-93) | Hydrostatic | | |
| | followed by | Test at | | |
| | Low Pressure | 1 psi/10 min | | |
| | Hydrostatic | after 16-hr | Oil Rating | |
| | Test (AATCC | Diesel Fuel | (AATCC 118) | |
| | 127) at | (AATCC | ePTFE | |
| Sample Info | psi/10 min | 127) | side | PU Side |
| ePTFE | NA | Failed | Failed | NA |
| | | | Oil 1 | |
| ePTFE | NA | Failed | Passed | NA |
| | | | Oil 7 | |
| ePTFE coated | Passed with no | Passed with | Passed | Passed |
| with microporous | leakage | no leakage | Oil 1 | Oil 3 |
| thermoplastic | | | | |
| polyurethane | | | | |
| ePTFE coated | Passed with no | Passed with | Passed | Passed |
| with microporous | leakage | no leakage | Oil 5 | Oil 6 |
| thermoplastic | | | | |
| polyurethane and | | | | |
| treated with | | | | |
| oleophobic | | | | |
| fluoroacrylate | | | | |
| polymer | | | | |
| ePTFE coated | Passed with | Passed with no | Passed | Passed |
| with microporous | no leakage | leakage | Oil 6 | Oil 7 |
| thermoplastic | | | | |
| polyurethane and | | | | |
| treated with | | | | |
| oleophobic | | | | |
| fluoroacrylate | | | | |
| polymer | | | | |

The final sheet material 10 may have a thickness between major surfaces of less than 100 micron, or 0.1 millimeters. Of course, such an example dimension need not be a limitation upon the present invention. This low thickness, along with a light weight, adds to the comfort level of the sheet material 10. In fact, at least one the materials of the layer 14 and the coating material 16 may enhance the mechanical properties of the polymer substrate 12. The sheet material 10 may also be combined with another fabric layer on both sides for use in the construction of outerwear, such as gloves, boots, tents, etc. In fact, at least one the materials of the layer 14 and the coating material 16 could provide for interfacial bonding to another porous substrate. Example uses of the sheet material 10 include, but are not limited to, gloves, hats, coats, jackets, shirts, pants, under garments, shoes, boots, protective wear, various other articles of clothing, backpacks, sleeping bags, tents, various other outdoor gear, and the like.

With regard to uses that involve something worn by a person, it is must be appreciated that as the person sweats both water vapor and liquid perspiration are generated on the skin. In such an application it is contemplated that the coating layer would innermost, toward the person and the substrate 12 would be outermost, away from the person. A high MVTR and air permeability may provide for this water vapor and liquid sweat to quickly pass through the sheet material 10. As such, the sheet material is quite useful for the use examples mentioned above concerning items that are worn by a person. Of course, the present invention is not limited to such uses and other uses are contemplated. Also, it is contemplated that the sheet material may include additional layers and/or the sheet material may be incorporated into multilayer sheet. Some examples of such additions to the sheet material and/or the use of sheet material being included into a multilayer sheet include the use of at least one of woven fabrics, nonwoven fabrics, knitted fabrics, and yarn. Of course, other materials and/or fabrics are contemplated.

The invention has been described with reference to the example embodiments described above. Modifications and alterations will occur to others upon a reading and understanding of this specification. Examples embodiments incorporating one or more aspects of the invention are intended to include all such modifications and alterations insofar as they come within the scope of the appended claims.

What is claimed is:

1. A porous composite membrane including:
a first microporous substrate of a first material;
a second, coating material joined to the first microporous substrate to form a bi-component arrangement with the first microporous substrate, the second material being different than the first material; and
a third, coating material applied to the bi-component arrangement, the third material being different than the first and second materials, the third material extending over at least a portion of surfaces of the bi-component arrangement which define the micropores.

2. The porous composite membrane as set forth in claim 1, wherein the membrane has an air permeability of at least 0.1 cfm per square foot of surface area of one side of the composite membrane at 1,000 Pascals differential pressure.

3. The porous composite membrane as set forth in claim 1, wherein the micropores are less than 100 microns.

4. The porous composite membrane as set forth in claim 1, wherein the first material includes at least one of fluoro-based polymer, polyurethane, cellulosic polymer, polyamide, polyimide, polycarbonate, polysulfone, and copolymer.

5. The porous composite membrane as set forth in claim 4, wherein the fluoro-based polymer includes at least one of polytetrafluoroethylene and polyvinylidene fluoride.

6. The porous composite membrane as set forth in claim 4, wherein the copolymer includes at least one of copolyester-polyether and copolyether-polyamide.

7. The porous composite membrane as set forth in claim 1, wherein the second, material includes at least one of polyurethane, fluorinated acrylate, fluorinated methacrylate, siloxane-based polymer, polyacrylic acid, copolymers of acrylamide.

8. The porous composite membrane as set forth in claim 7, wherein the second, coating material is a thermoplastic or a thermoset.

9. The porous composite membrane as set forth in claim 7, wherein the second, coating material is crosslinkable.

10. The porous composite membrane as set forth in claim 1, wherein the third material includes at least one of polyurethane, fluorinated acrylate, fluorinated methacrylate, siloxane-based polymer, polyacrylic acid, copolymers of acrylamide.

11. The porous composite membrane as set forth in claim 10, wherein the third material is a thermoplastic or a thermoset.

12. The porous composite membrane as set forth in claim 1, wherein at least one of the second and third materials enhances the mechanical properties of the first microporous substrate.

13. The porous composite membrane as set forth in claim 1, wherein at least one of the second and third materials changes oil repellent properties of the first microporous substrate.

14. The porous composite membrane as set forth in claim 1, wherein at least one of the second and third materials changes hydrophobic or water repellent properties of the first microporous substrate.

15. The porous composite membrane as set forth in claim 1, wherein at least one of the second and third materials changes the coefficient of friction of the first microporous substrate.

16. The porous composite membrane as set forth in claim 1, wherein at least one of the second and third materials provides for interfacial bonding to another porous substrate.

17. The porous composite membrane as set forth in claim 1, wherein at least one of the second and third materials increases resistance to liquid chemical intrusion into or through the pores of the first microporous substrate.

18. The porous composite membrane as set forth in claim 1, wherein the membrane has at least the following properties of waterproof, oleophobic, resistance to liquid chemical penetration.

19. The porous composite membrane as set forth in claim 1, wherein at least one of the coating materials is a microporous substrate.

20. The porous composite membrane as set forth in claim 1, wherein the second coating material and the third coating material are applied to the first microporous substrate of a first material.

21. A process of making a porous composite membrane as set forth within claim 1.

22. The process as set forth in claim 21, wherein the third material is applied by at least one of a) dispersion in a fluid, b) with the aid of a liquid carrier, and c) deposited by precipitation from a supercritical fluid, liquid, or gas.

23. The process as set forth in claim 22, wherein the liquid carrier includes at least one of an organic solvent and an inorganic solvent.

24. The process as set forth in claim 22, wherein the supercritical fluid, liquid, or gas includes carbon dioxide.

25. The process as set forth in claim 21, wherein the second material is joined to the first microporous substrate by at least one of a) chemical vapor deposition, b) plasma, c) knife coating process, d) transfer coating process, e) screen printing process, and f) gravure roll printing process.
